(19) United States
(12) Patent Application Publication
(10) Pub. No.: US 2011/0169794 A1
(43) Pub. Date: Jul. 14, 2011

(54) PHOTODETECTOR, PHOTODETECTOR ARRAY AND DISPLAY DEVICE WITH PHOTODETECTION

(75) Inventors: Yujiro HARA, Kanagawa-ken (JP); Yuki Kudo, Kanagawa-ken (JP); Jiro Yoshida, Kanagawa-ken (JP)

(73) Assignee: Kabushiki Kaisha Toshiba, Minato-ku (JP)

(21) Appl. No.: 13/051,612

(22) Filed: Mar. 18, 2011

Related U.S. Application Data
(63) Continuation of application No. PCT/JP09/65482, filed on Sep. 4, 2009.

(30) Foreign Application Priority Data
Sep. 19, 2008 (JP) 2008-241062

(51) Int. Cl. G09G 5/00; H01L 31/113

(52) U.S. Cl. 345/207; 257/290; 257/E31.085

(57) ABSTRACT

According to one embodiment, a photodetector includes a substrate, a first semiconductor region, a second semiconductor region, a third semiconductor region, an insulating film, a first electrode, a second electrode, and a shield film. The first semiconductor region is provided on a major surface of the substrate. The second semiconductor region and the third semiconductor region are provided in a substantially identical plane to the first semiconductor region. The second semiconductor region is contacted with the first semiconductor region and has an impurity concentration higher than the first semiconductor region. The third semiconductor region is contacted with the second semiconductor region. The shield film is provided on the insulating film and electrically connected to the first electrode. A periphery of the shield film is disposed to cover an interface between the second semiconductor region and the third semiconductor region in a planar view.

### CROSS-REFERENCE TO RELATED APPLICATION

This is a continuation application of International Application PCT/JP2009/065482, filed on Sep. 4, 2009. This application also claims priority to Japanese Application No. 2008-241062, filed on Sep. 19, 2008. The entire contents of each are incorporated herein by reference.

### FIELD

Embodiments described herein relate generally to a photodetector, a photodetector array, and a display device with photodetection.

### BACKGROUND

In recent years, photodetectors (e.g., photodiodes) using poly silicon or amorphous silicon formed by CVD method etc., on substrates have been developed actively to realize an illuminance detector of plane type by disposing the photodiodes in a matrix on a substrate. These photodiodes can be formed on a glass substrate by diverting thin-film transistor (TFT) array technology used in liquid-crystal displays (LCDs) etc.

In active-matrix flat display devices such as LCDs, it is possible to provide input functionality in addition to conventional functionality of displaying images by together disposing photodetectors, which consist of photodiodes, and TFTs for image display on pixels. Specifically, it is possible to realize flat display devices having input functionality for various uses with built-in photodetectors on pixels by detecting reflected light from an object on a display surface reflecting direct light of an optical pen or backlight. More specifically, in a device incorporating photodetectors consisting of photodiodes of PIN structure into a display device, a photodiode providing a shield film formed to shield a depletion layer, which is formed in an i-region when reverse bias is supplied to a pin structure of the photodetector, from stray light from a backlight etc., has been proposed (for example, refer to JP-A 2006-332287 (Kokai)).

### BRIEF DESCRIPTION OF THE DRAWINGS

FIGS. 1A and 1B are schematic views illustrating the configuration of a photodetector according to a first embodiment;

FIG. 2 is a schematic cross-sectional view illustrating the configuration of a photodetector of an experimental example;

FIGS. 3A to 3C are graphs illustrating characteristics of the photodetector of the experimental example;

FIGS. 4A and 4B are schematic views illustrating the configuration of a photodetector of a comparative example;

FIGS. 5A and 5B are schematic cross-sectional views illustrating the configuration of another photodetector according to the first embodiment;

FIG. 6 is a schematic view illustrating the configuration of a photodetector array according to a second embodiment; and

FIG. 7 is a schematic view illustrating the configuration of a display device according to a third embodiment.

### DETAILED DESCRIPTION

According to one embodiment, a photodetector includes a substrate, a first semiconductor region of a first conductivity type, a second semiconductor region of the first conductivity type, a third semiconductor region of a second conductivity type, an insulating film, a first electrode, a second electrode, and a shield film. The first semiconductor region is provided on a major surface of the substrate. The second semiconductor region is provided in a substantially identical plane to the first semiconductor region, is contacted with the first semiconductor region and has an impurity concentration higher than the first semiconductor region. The third semiconductor region is provided in a substantially identical plane to the second semiconductor region and contacted with the second semiconductor region. The insulating film is provided on the first semiconductor region, the second semiconductor region, and the third semiconductor region. The first electrode is provided on the insulating film and electrically connected to the first semiconductor region. The second electrode is provided on the insulating film and electrically connected to the third semiconductor region. The shield film is provided on the insulating film and electrically connected to the first electrode. A periphery of the shield film is disposed to cover an interface between the second semiconductor region and the third semiconductor region in a planar view.

Exemplary embodiments will now be described with reference to the drawings.

The drawings are schematic or conceptual; and the relationships between the thickness and width of portions, the proportions of sizes among portions, etc., are not necessarily the same as the actual values thereof. Further, the dimensions and proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

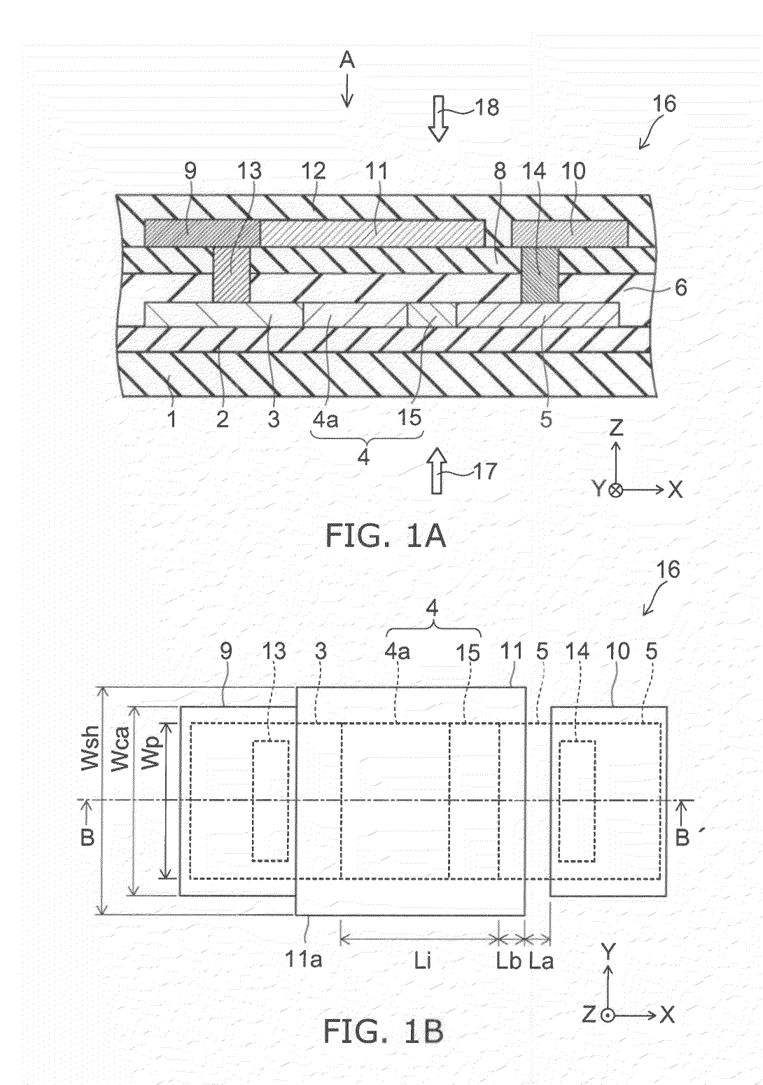

FIGS. 1A and 1B are schematic views illustrating the configuration of a photodetector according to a first embodiment.

Specifically, FIG. 1A is a cross-sectional view along B-B′ line in FIG. 1B, and FIG. 1B is a plan view taken from arrow A in FIG. 1A.

As illustrated in FIGS. 1A and 1B, in the photodetector 16 according to the first embodiment, an undercoating layer 2 consists of silicon nitride (SiN) or silicon oxide (SiOx) etc., is deposited on a glass substrate 1 by plasma chemical vapor deposition (CVD) etc., for example, with a thickness of 50 nm to 200 nm. A polysilicon film is deposited on the undercoating layer 2 with a thickness of about 50 nm to 100 nm.

The polysilicon film is provided between a p⁺ region 3 doped with high concentration of boron of about 1×10¹⁹ cm⁻³ and an n⁺ region 5 doped with high concentration of phosphorus of about 1×10¹⁹ cm⁻³, and provides a p− region 4 of which impurity concentration is lower than the p⁺ region 3 and the n⁺ region 5.

The p⁻ region 4 may be doped with concentration of boron of about 1×10¹⁵ cm⁻³ to 1×10¹⁷ cm⁻³.

In the photodetector 16 according to the embodiment, the p⁺ region 3 is a first semiconductor region having a first conductivity type, the n⁺ region 5 is a third semiconductor region having a second conductivity type different to the first conductivity type, and the p⁻ region 4 is a second semiconductor region.

Here, as illustrated in FIGS. 1A and 1B, a plane parallel to a major surface of the substrate 1 is set to be an X-Y plane, a direction perpendicular to the X-Y plane is set to be a Z-axis. In the example, an interface of the p⁻ region 4 and the n⁺ region 5 is substantially linear, and a direction parallel to an interface of the p⁺ region 4 and the n⁺ region 5 and perpendicular to the Z-axis is set to be a Y-axis. Further, a direction perpendicular to the Z-axis and the Y-axis is set to be an X-axis.

Further, as shown in FIGS. 1A and 1B, the p⁻ region 4 includes a depletion layer 15 and a region (non-depletion region) 4a which is not depleted. The depletion layer 15 extends from the interface of the p⁻ region 4 and the n⁺ region 5 toward the region 4a which is not depleted (a negative direction of the X-axis). A length of the depletion layer 15 (length in a view taken from the interface of the p⁻ region 4 and the n⁺ region 5, and length in the X-axis direction) varies with, for example, potentials of the p⁻ region 4 and the n⁺ region 5.

A silicon oxide film 6 is provided with for example, a film thickness of about 50 nm to 200 nm to cover the p⁺ region 3, the p⁻ region 4, and the n⁺ region 5. A silicon oxide film 8 is provided on the silicon oxide film 6 with for example, a film thickness of about 200 nm to 600 nm.

Metal such as Mo-W ally, Al, Mo, Ti, etc. is formed on the silicon oxide film 8 with for example, a film thickness of about 400 nm to 600 nm and patterned to form an anode electrode (first electrode) 9, a cathode electrode (second electrode) 10, and a shield film 11.

The anode electrode 9 is connected to the p⁺ region 3 via a contact 13 provided in the silicon oxide film 8 and the silicon oxide film 6. The cathode electrode 10 is connected to the n⁺ region 5 via a contact 14 provided in the silicon oxide film 8 and the silicon oxide film 6.

In the photodetector 16 according to the embodiment, the shield film 11 is electrically connected to the anode electrode 9. Further, in a planar view, the shield film 11 overlaps the interface of the p⁻ region 4 and the n⁺ region 5, and is disposed to cover the interface of the p⁻ region 4 and the n⁺ region 5, and the depletion layer 15. As a result, the shield film 11 shields the interface of the p⁻ region 4 and the n⁺ region 5, and the depletion layer 15 from stray light 18 from backlight etc.

In other words, a peripheral edge 11a of the shield film 11 is disposed to encircle the interface of the p⁻ region 4 and the n⁺ region 5 in a view taken in a direction perpendicular to the major surface of the substrate 1. Further, the peripheral edge 11a of the shield film 11 is disposed outside the depletion layer 15. Further, the peripheral edge 11a of the shield film 11 may be disposed outside the p⁻ region 4. As a result, a portion with the high light sensitivity of the photodetector 16 is shielded from the stray light 18.

Further, a silicon nitride film 12 is provided to cover the silicon oxide film 8, the anode electrode 9, the cathode electrode 10, and the shield film 11.

A length Li in the X-axis direction of the p⁻ region 4 interposed between the p⁺ region 3 and the n⁺ region 5 is, for example, 20 μm. A length Lb in the X-axis direction from the interface of the p⁻ region 4 and the n⁺ region 5 to the edge of shield film 11 is, for example, 5 μm. A gap La in the X-axis direction of the edge of the shield film 11 and an edge of the cathode electrode 10 is, for example, 5 μm. With respect to a direction perpendicular to the direction of the length Li, i.e., the Y-axis direction, a width Wp of the p⁻ region 4 is, for example, 40 μm, a width Wsh of the shield film 11 is, for example, 50 μm, and a width Wca of the cathode electrode 10 is for example, 44 μm.

The photodetector 16 is a lateral pin photodiode having such a structure. In the photodetector 16, incident light 17 to be detected enters, for example, from the substrate 1 side. The stray light 18 enters, for example, in a direction different to the incident light 17.

Here, a photodetector having a large ratio of current under light irradiation to dark current can be provided, for the shield film 11 surrounding the interface of the p⁻ region 4 and the n⁺ region 5, and being set to be the same potential as the anode electrode 9, as illustrated in FIGS. 1A and 1B.

The configuration of a photodetector according to the first embodiment is designed on the basis of new phenomena found out from results of experiments described below.

Inventors investigated influence of an applied voltage of a shield film to characteristics of a lateral PIN photodiode.

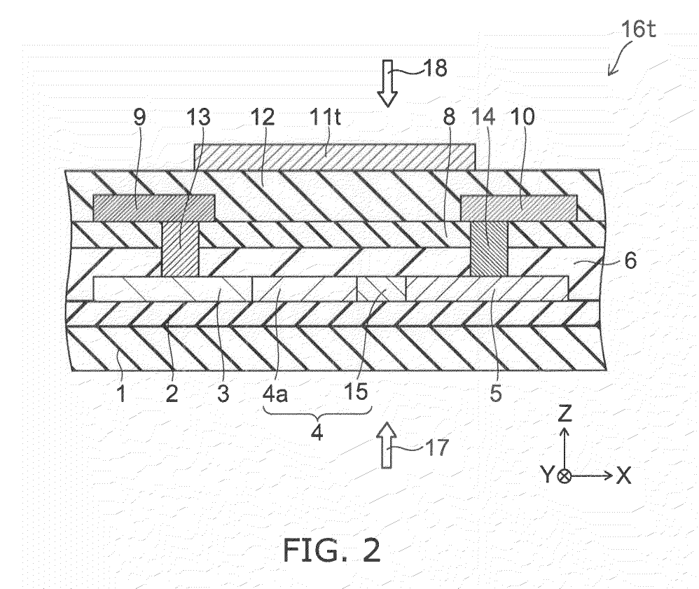

FIG. 2 is a schematic cross-sectional view illustrating the configuration of a photodetector of an experimental example.

As illustrated in FIG. 2, in the photodiode 16t used in the experiment, the p⁺ region 3 (P layer) being a p-type semiconductor layer, the n⁺ region 5 (N layer) being an n-type semiconductor layer, and the p⁻ region 4 (I layer) interposed between the P layer and the N layer in a planar view are provided on a undercoating layer formed on the substrate 1. The p⁺ region 3, the p⁻ region 4, and the n⁺ region 5 are formed with polysilicon of a polycrystalline semiconductor as one layer.

The silicon oxide film 6 and the silicon oxide film 8 being insulating films are provided on the polysilicon, and the anode electrode 9 and the cathode electrode 10 are provided on the silicon oxide film 8. The anode electrode 9 is electrically connected to the p⁺ region 3 via the contact 13 provided on the silicon oxide film 6 and the silicon oxide film 8. The cathode electrode 10 is electrically connected to the n⁺ region 5 via the contact 14 provided on the silicon oxide film 6 and the silicon oxide film 8.

The silicon nitride film 12 being an insulating film is provided on the anode electrode 9 and the cathode electrode 10, and a conductive film 11t is provided on the silicon nitride film 12. The conductive film 11t is Indium Tin Oxide (ITO).

Here, the conductive film 11t is disposed to overlap the depletion layer 15 extending from the interface of the p⁻ region 4 and the n⁺ region 5 toward the p⁻ region 4 in a planar view. However, the conductive film 11t is configured to be electrically insulated from the anode electrode 9 and the cathode electrode 10, and to be applied with an arbitrary voltage independent of these electrodes.

One of characteristic indexes of a photodiode is a light-dark ratio Iph/Idark, where the light current Iph is current flowing under incident light desired to be detected and radiated on an inverse biased photodiode, and the dark current Idark is current flowing without the incident light. The light-dark ratio Iph/Idark was examined to change the voltage applied to the cathode electrode 10 in the experiment.

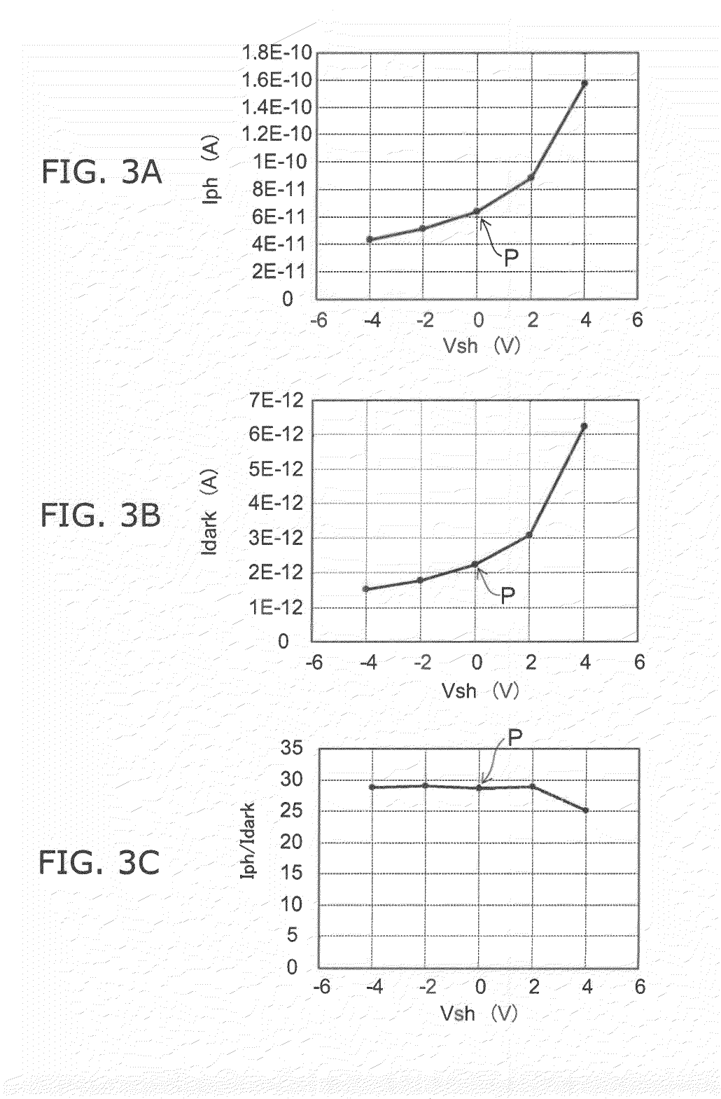

FIGS. 3A to 3C are graphs illustrating characteristics of the photodetector of the experimental example.

FIG. 3A, FIG. 3B and FIG. 33c show the shield film potential Vsh dependency of the light current Iph, the dark current Idark, and light-dark ratio Iph/Idark, respectively, in the case where the anode electrode 9 is grounded and the cathode potential Vb applied to the cathode electrode 10 is kept positive constant of 5 V, while changing the shield film potential Vsh applied to the conductive film 11t. In FIGS. 3A to 3C, horizontal axes represent the shield film potential Vsh and vertical axes represent the light current Iph, the dark current Idark, and the light-dark ratio Iph/Idark, respectively.

The point P shown in FIGS. 3A to 3C is a potential value at which the shield film potential Vsh of the photodetector of the experimental example has the same potential condition as the shield film voltage of FIGS. 1A and 1B illustrated as the configuration of the photodetector according to the first embodiment.

The light current Iph is nearly proportional to intensity of irradiated light. Incident light of 1000 lux is used here. The incident light enters from the conductive film 11t side to a semiconductor region.

As illustrated in FIGS. 3A to 3C, the light current Iph and the dark current Idark increase as the shield film potential Vsh increases from negative to positive.

The light-dark ratio Iph/Idark is nearly constant as the shield film potential Vsh increases from negative to positive low value, but decreases as the shield film potential Vsh is close to the cathode potential Vb (here, 5 V). In other words, degradation of the light-dark ratio Iph/Idark can be reduced by lowering the shield film potential Vsh than the cathode potential Vb, for example, negative potential.

The phenomena may be caused by a size of the depletion layer 15 extending to the p⁻ region 4 not only being affected by a lateral electric field accompanied with cathode potential Vb and but also being affected by a longitudinal electric field accompanied with the shield film potential Vsh. Further, the phenomena may be caused by enlargement of a volume of the depletion layer 15 when the shield film potential Vsh is positive.

As described above, it is found that the conductive film 11t is necessarily applied with the potential lower than the cathode potential Vb, for example, 0 potential not to degrade the light-dark ratio Iph/Idark.

The configuration of the photodetector 16 according to the first embodiment is configured on the basis of above-described find. In the photodetector 16, the shield film 11 shields the interface of the p⁻ region 4 and the n⁺ region 5 and is set as the same potential as the anode electrode 9 to be applied with 0 potential. Therefore, the dark current Idark can be reduced while stray light 18 from backlight etc. does not to enter the depletion layer 15, and the light-dark ratio Iph/Idark can be increased. Further, the light-dark ratio Iph/Idark can be increased by setting the potential of the shield film 11 the same potential as the anode electrode 9 as described above of the experiment.

The photodetector 16 according to the embodiment provides a photodetector having the large ratio of current flowing under incident light to current flowing without the incident light.

### Comparative Example

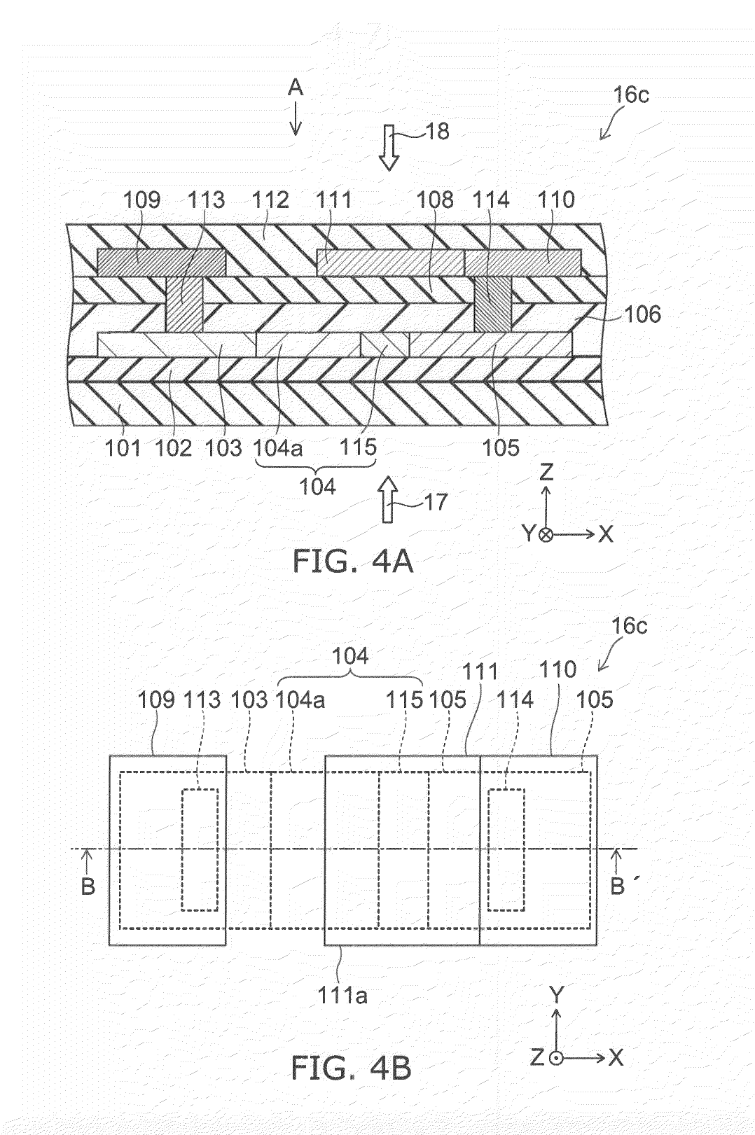

FIGS. 4A and 4B are schematic views illustrating the configuration of a photodetector of a comparative example.

Specifically, FIG. 4A is a cross-sectional view along B-B′ line in FIG. 4B, and FIG. 4B is a plan view taken from arrow A in FIG. 4A.

As illustrated in FIGS. 4A and 4B, in the photodetector 16c of the comparative example, a p⁺ region 103 being a p-type semiconductor layer (p-layer), an n⁺ region 105 being an n-type semiconductor layer (n-layer), and a p− region 104 (i-layer) interposed between the p⁺ region 103 and the n⁺ region 105 are provided on the undercoating layer 102 formed on a substrate 101 and formed of polysilicon of a polycrystalline semiconductor as one layer.

A silicon oxide film 106 and 108 being an insulting film is formed on the polysilicon, and an anode electrode 109 and a cathode electrode 110 are formed on the silicon oxide film 108.

The anode electrode 109 is electrically connected to the p⁺ region 103 via a contact 113 provided in the silicon oxide film 106 and 108, and the cathode electrode 110 is electrically connected to the n⁺ region 105 via a contact 114 provided in the silicon oxide film 106 and 108.

A photodiode of pin structure is reversely biased with applying a positive voltage to the cathode electrode 110 compared to the anode electrode 109 and a depletion layer 115 extends from an interface of the n⁺ region 105 and the p⁻ region 104 to the p⁻ region 104 side.

In the photodetector 16c of the comparative example, a shield film 111 disposed to cover a region from the interface of the n⁺ region 105 and the p⁻ region 104 to the p⁻ region 104 side is electrically connected to the cathode electrode 110, and functions to shield the stray light 18 from a backlight etc. from entering the depletion layer 115.

However, in a photodetector having such configuration, characteristics of the photodetector may be degraded because the shield film 111 disposed on the depletion layer 115 is applied with the same voltage as the bias voltage Vb being applied to cathode electrode 110 and the potential of the shield film 111 electrically affects the depletion layer 115. Specifically, the ratio of current under light irradiation to dark current is small.

In contrast, as described above, in the photodetector 16 according to the first embodiment, the photodetector having the large ratio of current under light irradiation to dark current can be provided, because the shield film 11 is applied with the same potential as the anode electrode and provided to cover the interface of the n⁺ region 105 and the p⁻ region 104.

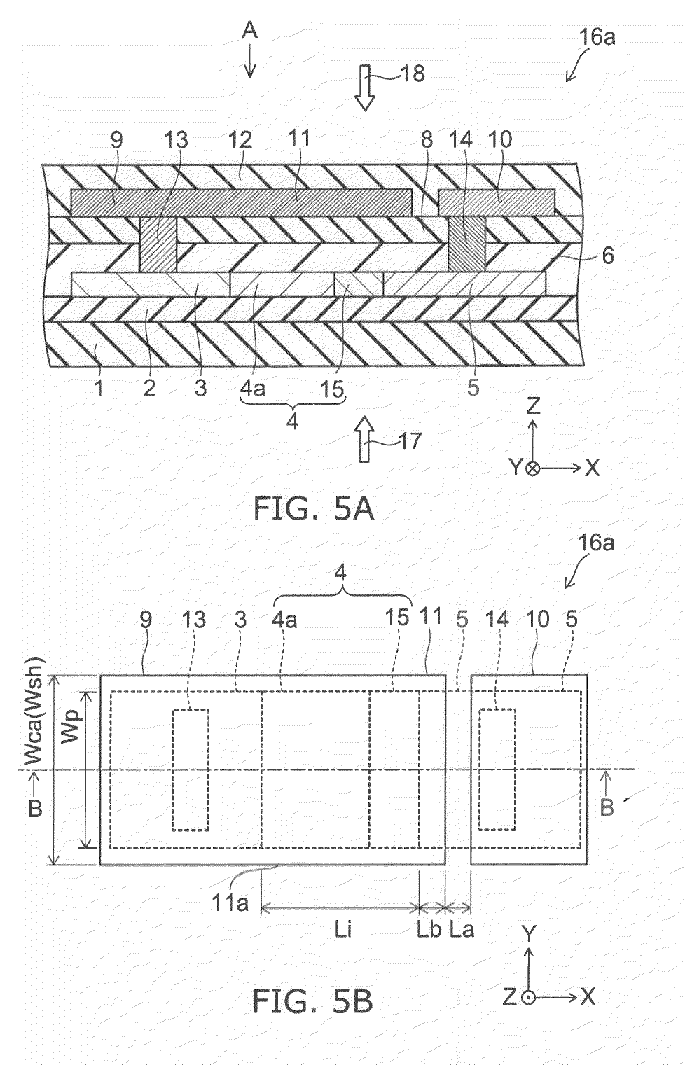

FIGS. 5A and 5B are schematic cross-sectional views illustrating the configuration of another photodetector according to the first embodiment.

As illustrated in FIGS. 5A and 5B, in another photodetector 16a according to the first embodiment, a width Wsh in the Y-axis direction of the shield film 11 is the same as the width Wca in the Y-axis direction of an anode electrode 9. The rest is the same as the photodetector 16 and a detailed description is omitted.

In the photodetector 16a, the width in the Y-axis direction of the shield film 11 is the same as the width in the Y-axis direction of the anode electrode 9 and the shield film 11 is configured to extend in the X-axis direction of the anode electrode 9. In the photodetector 16a having such structure, the shield film 11 is provided to have the same potential as the anode electrode 9 and provided to cover the interface of the p⁻ region 4 and the n⁺ region 5. Thereby, the photodetector having the large ratio of current flowing under incident light to current flowing without the incident light can be provided.

In each of the photodetectors 16 and 16a according to the embodiment, the periphery 11a of the shield film 11 is disposed to cover the interface of the p− region 4 and the n⁺ region 5, and the shield film 11 covers the interface and shields the light from entering the interface. Thereby, the ratio of current flowing under incident light to current flowing without the incident light can be enlarged by decreasing dark current.

Further, it is preferable to be disposed for the periphery 11a of the shield film 11 to cover the depletion layer 15 formed in the p− region 4 in a planar view. Thereby, the ratio of current under the incident light to current without the incident light can be enlarged further.

In each of the photodetectors 16 and 16a according to the embodiment illustrated in FIGS. 1A and 1B and FIGS. 5A and 5B, although the interface of the p⁻ region 4 and the n⁺ region 5 is a straight line parallel to the Y-axis direction, it is not limited to this but the interface of the p− region 4 and the n⁺ region 5 may be in arbitrary shape. For example, the interface of the p⁻ region 4 and the n⁺ region 5 can be made into the shape of two neighboring edges of a rectangle (“L-character shape”), the shape of three neighboring edges of a rectangle, the shape of neighboring edges of arbitrary polygon, or the shape of an arc, etc. Further, in each of the photodetectors 16 and 16a according to the embodiment, although the interface of the p− region 4 and the n⁺ region 5 is disposed in a linear arrangement, but it may be disposed in an arbitral arrangement, for example, the p⁻ region 4 and the n+region 5 may be disposed to surround at least a part of the p⁺ region 3.

In these cases, the interface of the p⁻ region 4 and the n⁺ region 5 is covered with the shield film 11.

Each of the photodetectors 16 and 16a is applicable to for example, photodetector arrays, display devices with an photodetection, etc.

### Second Embodiment

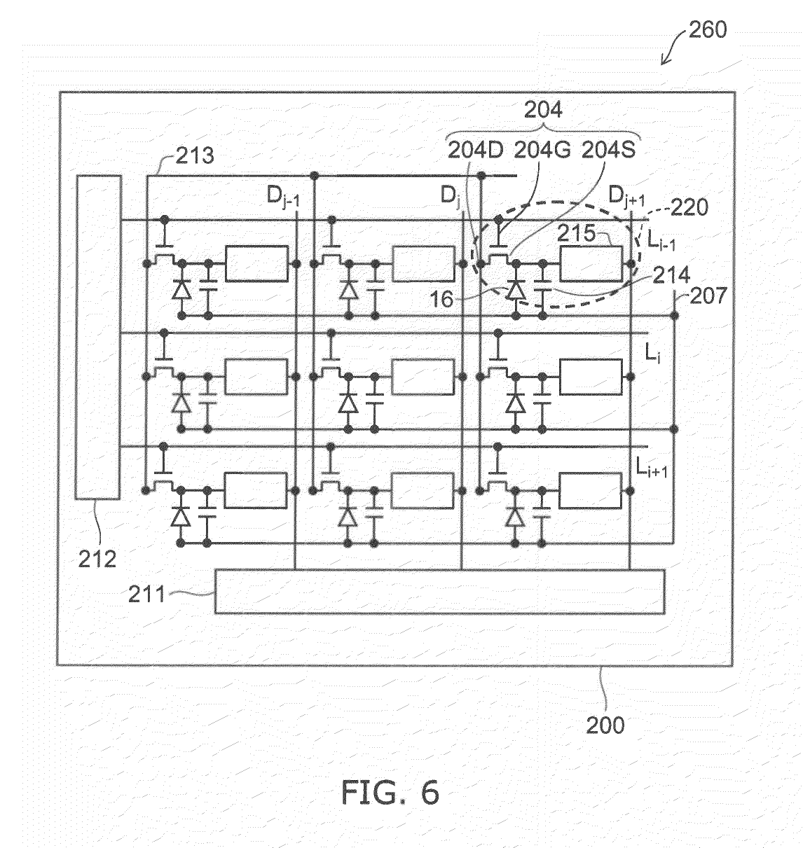

FIG. 6 is a schematic view illustrating the configuration of a photodetector array according to a second embodiment.

As illustrated in FIG. 6, the photodetector array 260 provides a plurality of scan lines Li extending in a first direction, a plurality of sense lines Dj extending in a second direction intersecting with the first direction, a plurality of photodetecting elements 220 provided corresponding to the intersections of each of the plurality of scan lines Li and each of the plurality of sense lines Dj, a scan circuit 212 connected to each of the scan lines Li, a sense circuit 211 connected to each of the sense lines Dj, and a power supply line 213. Each of i and j is an integer equal to two or more.

In other words, the photodetector array 260 includes the plurality of photodetector elements 220 (portion surrounded with the dashed line).

Each of the photodetector elements 220 includes a reset transistor 204 (the first transistor) having a gate 204G connected to the scan line Li, a drain 204D connected to the power supply line 213, a source 204S, and a channel layer (not shown), and the photodetector 16 connected to a source 204S of the reset transistor 204, an accumulation capacitor 214, and an amplifier 215.

In this case, the cathode electrode 10 of the photodetector 16 is connected with the source 204S of the reset transistor 204. The anode electrode 9 of the photodetector 16 is connected to a common terminal 207.

One terminal of the accumulation capacitor 214 is connected to the cathode electrode 10 of the photodetector 16 and one other terminal of the accumulation capacitor 214 is connected to the common terminal 207. The input terminal of the amplifier 215 is connected to the cathode electrode 10 of the photodetector 16 and the output terminal of the amplifier 215 is connected to the sense line Dj.

The photodetector 16a may be used although the photodetector 16 is used in the specific example. In other words, the photodetector array 260 according to the embodiment can use at least one of the photodetectors 16 and 16a.

The scan line Li, the sense line Dj, and the photodetecting elements 220 can be provided on a substrate 200 consisting of glass etc. The thin-film transistor (TFT) consisting of polysilicon can be used for the reset transistor 204. At least a part of each of the scan circuit 212 and the sense circuit 211 can be formed on the substrate 200 as a peripheral circuit, or it can also be provided on a substrate different from the substrate 200.

Operation of the photodetector array 260 according to the embodiment will now be described.

Cathode potential is applied to the power supply line 213, and grand potential is applied to the common terminal 207. One scan line Li is chosen line-sequentially at a time by the scan circuit 212, and cathode potential is applied to the cathode electrode 10 via the reset transistor 204. The reverse bias voltage is applied to the photodetector 16 because the anode electrode 9 is applied with the grand potential. The photoelectric current depending on the amount of optical irradiation flows and an electric charge is accumulated in the accumulation capacitor 214 when the photodetector 16 is irradiated with light in this state.

Then, the electric charge accumulated in the accumulation capacitor 214 depending on the irradiation light of the photodetecting element 220 in the intersection position i and j of the scan line Li and the sense line Dj can be read by choosing the amplifier 215 line-sequentially by a second scan line (not shown), and reading the voltage of the sense line Dj line-sequentially by the sense circuit 211.

Therefore, the intensity distribution of the light irradiated in two dimensions can be detected by the photodetector array 260 having a plurality of the photodetecting elements 220 arranged in two dimensions, and can be used as a two dimensional optical sensor.

In the photodetector array 260 according to the embodiment, the photodetector array having the large ratio of current under the incident light to current without the incident light can be provided by using at least one of the photodetectors 16 and 16a according to the first embodiment.

### Third Embodiment

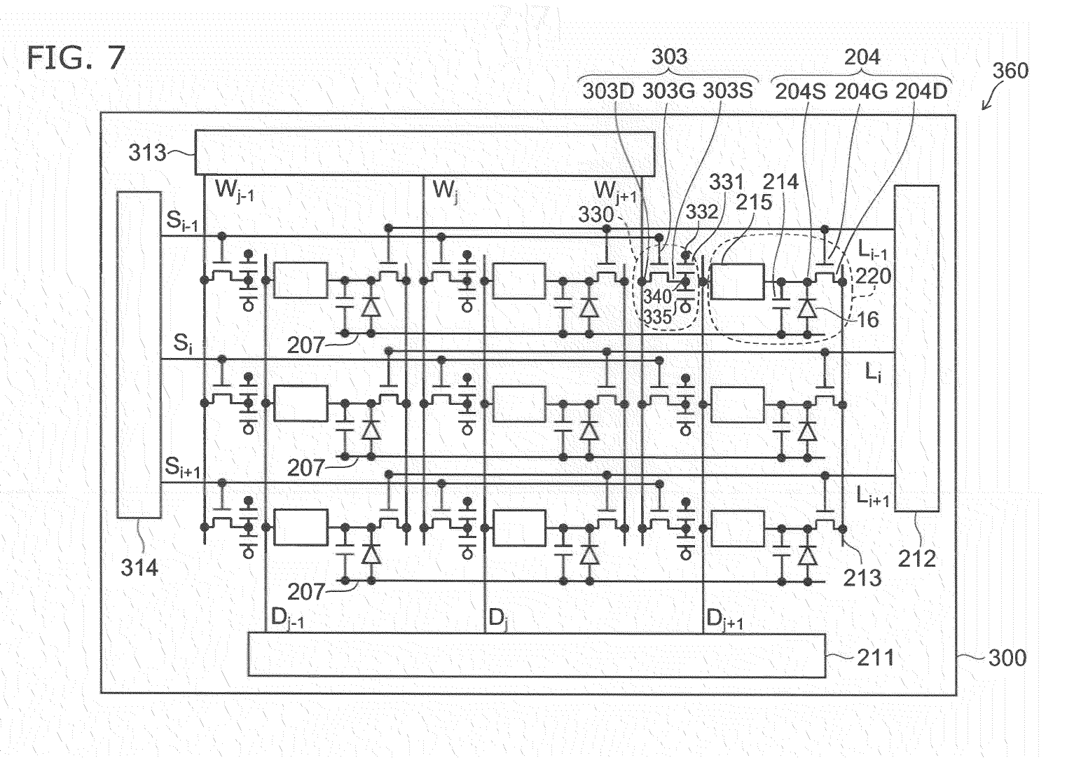

FIG. 7 is a schematic view illustrating the configuration of a display device according to a third embodiment.

As illustrated in FIG. 7, the display device 360 with photodetection according to the third embodiment includes a plurality of scan lines Li extending in a first direction, a plurality of sense lines Dj extending in a second direction intersecting with the first direction, a plurality of photodetecting elements 220 (portion surrounded with the dashed line) provided corresponding to the intersections of each of the plurality of scan lines Li and each of the plurality of sense lines Dj, the scan circuit 212 connected to the scan lines Li, and the circuit 211 connected to the sense lines Dj.

Further, the display device 360 includes a plurality of display scan lines Si extending in the first direction, a plurality of signal lines Wj extending in the second direction intersecting with the first direction, a display scan circuit 314 connected to the display scan lines Si, a signal circuit 313 connected to the signal lines Wj, and a plurality of display elements (portion surrounded with the dashed line), each of which has a pixel electrode 340, provided corresponding to the intersections of each of the display scan lines Si and each of the signal lines Wj, a plurality of counter electrodes 332, each of which is confronted with the pixel electrode 340, an optical layer 331, of which the optical characteristic changes depending on the voltage applied between the pixel electrode 340 and the counter electrode 332, provided between the counter electrode 332 and the pixel electrode 340.

Thus, the display device 360 with photodetection includes a plurality of photodetecting elements 220 and a plurality of display elements 330. In the specific example, the plurality of display scan lines Si are provided apart from the plurality of scan lines Li.

Since the photodetecting element 220 can be made to be the same as that of the case of the photodetector array 260 according to the second embodiment, a detailed description is omitted.

Each of display elements 330 includes the display transistor 303 (the second transistor) having the gate 303G connected to the display scan line Si, the drain 303D connected to the signal line Wj, the source 303S connected to the pixel electrode 340, and a channel layer (not shown).

In the specific example, each of display elements 330 further includes a second accumulation capacitor 335 connected to the source 303S of the display transistor 303.

For example, a liquid crystal can be used for the optical layer 331 in the display element 330. However, not limited to this, organic electroluminescence can be used for the optical layer 331 that optical characteristic just change based on the voltage applied between the pixel electrode 340 and the counter electrode 332.

In the display element 330, the counter electrode 332 confronted with the pixel electrode 340 may be provided on the substrate 300. In the case where a liquid crystal is used as the optical layer 331, another counter substrate is provided in approximately parallel to the substrate 300, and the liquid crystal is interposed therebetween. For example, the pixel electrode 340 and the counter electrode 332 are provided in a saw-tooth shape on the substrate 300, and displaying is performed by changing the arrangement direction of the liquid crystal by electric field generated with the voltage between the pixel electrode 340 and the counter electrode 332. At this time, the liquid crystal mainly changes arrangement within a plane parallel to the substrate 300.

Further, in the display element 330, the counter electrode 332 confronted with the pixel electrode 340 can be provided in the counter substrate confronted with the substrate 300. The counter electrode 332 at this time is provided as the common electrode on the counter substrate. When using a liquid crystal as the optical layer 331, the liquid crystal is interposed among these substrates. Displaying is performed by changing the arrangement direction of the liquid crystal with the voltage between the pixel electrode 340 and the counter electrode 332. At this time, the liquid crystal in, for example, twisted nematic mode can be used for the liquid crystal. Thus, the counter electrode 332 may be provided on the counter substrate different from the substrate 300, on which the scan lines Li, the sense lines Dj, and the photodetecting elements 220 are provided, and the counter electrode 332 may be provided in common in each of the display elements 330. Thus, at least some of the display elements 330 are provided on the substrate 300 on which the scan lines Li, the sense lines Dj, and the photodetecting elements 220 are provided.

At least some of the scan lines Li, the sense lines Dj, the signal lines Wj, the photodetecting elements 220, and the display elements 330 can be provided on the substrate 300 consisting of glass etc. A thin-film transistor (TFT) made of polysilicon can be used for the reset transistor 204 and the display transistor 303. A part of the scan circuit 212, the sense circuit 211, the display scan circuit 314, and the signal circuit 313 can be provided on the substrate 300 as a peripheral circuit, and can be provided on a substrate different from the substrate 300.

Operation of the photodetecting element 220, the scan circuit 212, and the sense circuit 211 are the same as those of the photodetector array 260 according to the second embodiment, and detailed description is omitted.

In each of the display element 330, the display transistor 303 is turned ON line-sequentially by the scan circuit 212, and a desired electric charge is written in the pixel electrode 340 of each display element 330 from the signal circuit 313 synchronizing with it, and desired voltage is applied to an optical layer and displaying is performed.

In the display device 360 with photodetection according to the embodiment, the display device with photodetection enabled to detect enlarged current ratio of the optical irradiation to dark current can be provided by using at least one of the photodetectors according to the embodiment for each of the photodetecting element 220.

A display device with photodetection capable of inputting color images are configurable by providing a plurality of coloring layers (for example, color filters) having different spectral characteristics in a portion of the photodetector 16 of each photodetecting element 220 in the display device 360 with photodetection according to the embodiment. In this case, the color filters provided for the display element 330 may be used as a plurality of color layers having different spectral characteristics.

Hereinabove, although the first conductivity type is used as a p-type and the second conductivity type is used as an n-type, these can be replaced mutually. In other words, the first conductivity type is used as an n-type, and the second conductivity type is used as a p-type, for example, the first semiconductor region may be an n⁺ region, the second semiconductor region may be an n⁻ region, and the third semiconductor region may be a p⁺ region. Also in this case, the shield film 11 covers the boundary of second semiconductor region and the third semiconductor region to shield, and is applied with the same potential as the potential applied to the electrode connected to the first semiconductor region.

In the display device with photodetection according to the embodiment, irradiation of the light to the photodetector 16 includes irradiation of the light from, for example, an optical pen etc., the illumination light from the circumference, the light illuminated from the backlight in the display device and reflected by objects. Thereby, the display device with photodetection for various uses is realizable.

Hereinabove, exemplary embodiments are described with reference to specific examples. However, the embodiments are not limited to these specific examples. For example, one skilled in the art may similarly practice the embodiments by appropriately selecting specific configurations of components included in photodetectors, photodetector array, and display devices with photodetection from known art. Such practice is included in the scope of the embodiments to the extent that similar effects thereto are obtained.

Further, any two or more components of the specific examples may be combined within the extent of technical feasibility and are included in the scope of the embodiments to the extent that the purport of the embodiments is included.

Moreover, all photodetectors, photodetector array, and display devices with photodetection practicable by an appropriate design modification by one skilled in the art based on the photodetectors, the photodetector array, and the display devices with photodetection described above as exemplary embodiments also are within the scope of the embodiments to the extent that the purport of the embodiments is included.

Furthermore, various modifications and alterations within the spirit of the embodiments will be readily apparent to those skilled in the art. All such modifications and alterations should therefore be seen as within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A photodetector, comprising:
a substrate;
a first semiconductor region of a first conductivity type provided on a major surface of the substrate;
a second semiconductor region of the first conductivity type provided in a substantially identical plane to the first semiconductor region of the first conductivity type, the second semiconductor region contacted with the first semiconductor region and having an impurity concentration higher than the first semiconductor region;
a third semiconductor region of a second conductivity type provided in a substantially identical plane to the second semiconductor region, the third semiconductor region contacted with the second semiconductor region;
an insulating film provided on the first semiconductor region, the second semiconductor region, and the third semiconductor region;
a first electrode provided on the insulating film and electrically connected to the first semiconductor region;
a second electrode provided on the insulating film and electrically connected to the third semiconductor region; and
a shield film provided on the insulating film and electrically connected to the first electrode, a periphery of the shield film disposed to cover an interface between the second semiconductor region and the third semiconductor region in a planar view.

2. The photodetector according to claim 1, wherein the periphery of the shield film is disposed to cover a depletion layer being formed in the second semiconductor region in a view taken along a direction perpendicular to the major surface of the substrate.

3. The photodetector according to claim 1, wherein the periphery of the shield film is disposed to cover the second semiconductor region in a view taken along a direction perpendicular to the major surface of the substrate.

4. The photodetector according to claim 1, wherein the first electrode, the second electrode, and the shield film are provided in a substantially identical plane.

5. The photodetector according to claim 1, wherein the shield film is formed of substantially identical material to the first electrode.

6. The photodetector according to claim 1, wherein
a length along a first direction of the shield film is longer than a length along the first direction of the first electrode,
the first direction is parallel to the interface between the second semiconductor region and the third semiconductor region and parallel to the major surface of the substrate.

7. The photodetector according to claim 1, wherein
a length along a first direction of the shield film is equal to a length along the first direction of the first electrode,
the first direction is parallel to the interface between the second semiconductor region and the third semiconductor region and parallel to the major surface of the substrate.

8. The photodetector according to claim 1, wherein the shield film is contacted to the first electrode.

9. The photodetector according to claim 1, wherein at least one of the first semiconductor region, the second semiconductor region and the third semiconductor region is formed of polysilicon.

10. The photodetector according to claim 1, wherein
the first conductivity type is a p-type, the second conductivity type is an n-type.

11. A photodetector array, comprising:
a plurality of scan lines extending in a first direction;
a plurality of sense lines extending in a second direction intersecting with the first direction;
a plurality of photodetecting elements provided corresponding to intersections of each of the plurality of scan lines and each of the plurality of sense lines;
a scan circuit connected to the scan lines; and
a sense circuit connected to the sense lines,
each of the photodetecting elements including:
a first transistor having a gate connected to one of the scan lines, a drain connected to one of the sense lines, a source, and a channel layer; and
a photodetector being connected to the source of the first transistor,
the photodetector including:
a substrate;
a first semiconductor region of a first conductivity type provided on a major surface of the substrate;
a second semiconductor region of the first conductivity type provided in a substantially identical plane to the first semiconductor region of the first conductivity type, the second semiconductor region contacted with the first semiconductor region and having an impurity concentration higher than the first semiconductor region;
a third semiconductor region of a second conductivity type provided in a substantially identical plane to the second semiconductor region, the third semiconductor region contacted with the second semiconductor region;
an insulating film provided on the first semiconductor region, the second semiconductor region, and the third semiconductor region;
a first electrode provided on the insulating film and electrically connected to the first semiconductor region;
a second electrode provided on the insulating film and electrically connected to the third semiconductor region; and
a shield film provided on the insulating film and electrically connected to the first electrode, a periphery of the shield film disposed to cover an interface between the second semiconductor region and the third semiconductor region in a planar view.

12. The array according to claim 11, wherein the periphery of the shield film is disposed to cover a depletion layer being formed in the second semiconductor region in a view taken along a direction perpendicular to the major surface of the substrate.

13. The array according to claim 11, wherein the periphery of the shield film is disposed to cover the second semiconductor region in a view taken along a direction perpendicular to the major surface of the substrate.

14. The array according to claim 11, wherein the first electrode, the second electrode, and the shield film are provided in a substantially identical plane.

15. The array according to claim 11, wherein the shield film is formed of substantially identical material to the first electrode.

16. A display device, comprising:
a plurality of scan lines extending in a first direction;
a plurality of sense lines extending in a second direction intersecting with the first direction;
a plurality of photodetecting elements provided corresponding to intersections of each of the plurality of scan lines and each of the plurality of sense lines;
a scan circuit connected to the scan lines;
a sense circuit connected to the sense lines;
a plurality of signal lines extending in the second direction;
a signal circuit connected to the signal lines;
a plurality of display elements provided corresponding to intersections of each of the plurality of scan lines and each of the plurality of signal lines, each of the display elements having a pixel electrode;
a counter electrode confronting the pixel electrode; and
an optical layer provided between the pixel electrode and the counter electrode, optical characteristics of the optical layer being changed depending on a voltage applied between the pixel electrode and the counter electrode,
each of the photodetecting elements including:
a first transistor having a gate connected to one of the scan lines, a drain connected to one of the sense line, a source, and a channel layer; and
a photodetector being connected to the source of the first transistor,
each of the display elements including:
a second transistor having a gate being connected to one of the scan lines, a drain being connected to one of the signal lines, a source being connected to the pixel electrode, and a channel layer,
the photodetector including:
a substrate;
a first semiconductor region of a first conductivity type provided on a major surface of the substrate;
a second semiconductor region of the first conductivity type provided in a substantially identical plane to the first semiconductor region of the first conductivity type, the second semiconductor region contacted with the first semiconductor region and having an impurity concentration higher than the first semiconductor region;
a third semiconductor region of a second conductivity type provided in a substantially identical plane to the second semiconductor region, the third semiconductor region contacted with the second semiconductor region;
an insulating film provided on the first semiconductor region, the second semiconductor region, and the third semiconductor region;
a first electrode provided on the insulating film and electrically connected to the first semiconductor region;
a second electrode provided on the insulating film and electrically connected to the third semiconductor region; and
a shield film provided on the insulating film and electrically connected to the first electrode, a periphery of the shield film disposed to cover an interface between the second semiconductor region and the third semiconductor region in a planar view.

17. The device according to claim 16, wherein the periphery of the shield film is disposed to cover a depletion layer being formed in the second semiconductor region in a view taken along a direction perpendicular to the major surface of the substrate.

18. The device according to claim 16, wherein the periphery of the shield film is disposed to cover the second semiconductor region in a view taken along a direction perpendicular to the major surface of the substrate.

19. The device according to claim 16, wherein the first electrode, the second electrode, and the shield film are provided in a substantially identical plane.

20. The device according to claim 16, wherein the shield film is formed of substantially identical material to the first electrode.
